(19) United States
(12) Patent Application Publication
(10) Pub. No.: US 2002/0079832 A1
(43) Pub. Date: Jun. 27, 2002

(54) Electroluminescent device and a method of manufacturing thereof

(75) Inventors: Henricus Franciscus Johannus Jacobus Van Tongeren, Eindhoven (NL); Paulus Cornelis Duineveld, Eindhoven (NL)

Correspondence Address: Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 10/024,783

(22) Filed: Dec. 20, 2001

(30) Foreign Application Priority Data
Dec. 22, 2000 (EP) 00204813.0

(51) Int. Cl. H01J 1/62

(52) U.S. Cl. 313/504

(57) ABSTRACT

An electroluminescent device comprises a pattern-wise ink-jet printed electrode. The electrode supplies charges to an electroluminescent layer of the electroluminescent device and comprises a metal or a metal alloy. In a method of manufacturing such an electroluminescent device, the electrode is formed by ink-jet printing molten metal or metal alloy.

The invention relates to an electroluminescent device and a method of manufacturing thereof.

Generally, an electroluminescent (EL) device is a device comprising EL material capable of emitting light when a current is passed through it, the current being supplied by means of electrodes. If the EL material or, if present, any other functional material disposed between the electrodes is of organic or polymeric nature the device is referred to as an organic or polymer(ic) EL device respectively. In the context of the invention, the term organic includes polymeric.

EL devices of the diode type, also referred to as light-emitting diodes, preferentially pass current in one direction and generally comprise EL material disposed between a hole-injecting electrode (also referred to as the anode), an electron-injecting electrode (also referred to as the cathode). Upon application of a suitable voltage, holes and electrons are injected into the EL material via the anode and cathode respectively. Light is produced by radiative recombination of holes and electrons inside the EL material. Using different organic EL materials, the color of the light emitted can be varied.

EL devices can be used as light sources and, in particular those of the organic type, are suitable for large area lighting applications such as a back light for a display. (Organic) EL devices comprising a plurality of electroluminescent elements (hereinafter also referred to as pixels) suitable for display purposes such as a monochrome or multi-color display device, a still image display, a segmented display device, or a matrix display of the passive or active type. Organic and in particular polymer EL devices can be made flexible or shaped allowing display applications not realizable with rigid and/or flat displays.

In U.S. Pat. No. 5,701,055 an electroluminescent display panel having a plurality of emitting portions is disclosed. The panel comprises first electrodes onto which organic functional layers are formed onto which second electrodes are formed. The panel further comprises electrical insulating ramparts projecting from the substrate. The ramparts have overhanging sections projecting in a direction parallel to the substrate. By providing shadow regions for the flux of metal vapor used to deposit the second electrode layer, the ramparts serve to provide a patterned second electrode layer.

A drawback of the known EL display panel is that the deposition of the second electrode layer is performed using a vacuum deposition method. Vacuum-based deposition methods are generally batch methods which require vacuum expensive equipment, are relatively time-consuming and not particularly suited to provide thick films.

It is an object of the invention, inter alia, to alleviate these drawbacks. Specifically, the invention aims to provide an electroluminescent device having a patterned electrode which can be easily and efficiently manufactured in mass-fabrication if desired in a continuous process. The EL device should be such that its manufacture does not involve the use of vacuum equipment. In its broadest sense, the device is to be such that the electrode can be patterned reliably and precisely without the help of ramparts or other structures the formation of which require additional process steps.

In accordance with the invention, these and other objects are achieved by an electroluminescent device comprising a pattern-wise ink-jet printed electrode for supplying charges to an electroluminescent layer of the electroluminescent device, the electrode comprising a metal or a metal alloy.

By providing an ink-jet printed patterned electrode an EL device which can be easily and efficiently manufactured in mass-fabrication is obtained. Ink-jet printing is a reliable deposition method capable of providing high through-put and high-resolution and can be suitably applied in a continuous process. Patterns having characteristic minimum features sizes of as low as 20 μm can be accurately and routinely manufactured using conventional low-cost equipment.

When deposited on a substrate surface the ink adopts the natural shape of a fluid would adopt. This natural is characterized by the contact angle of the ink with respect to the substrate. Parameters which influence the natural shape and size of the deposited ink are, the amount of and rate at which ink is discharged (drop volume times drop frequency), the nozzle diameter and the speed at which the ink-jet head is moved relative the substrate. In the case of a jet of ink drops, the distance measured on the substrate between successively deposited drop inks is an important parameter to control the size and shape of an ink-jetted electrode. Because ink adopts a natural shape and size when deposited on a substrate, the electrode can be patterned without using ramparts or similar structures the formation of which require additional process steps.

In the context of the invention, the term ink-jet printing refers to the release of a jet of ink (fluid) from a nozzle or more than one nozzle (multi-nozzle). The jet may consist of individual drops or may be a continuous jet, the latter arrangement also being referred to as dispensing. A desired pattern is obtained by moving the ink-jet head relative to the surface on which the ink is to be deposited in response to a time-dependent input data signal provided by driver electronics to the ink-jet head.

In the context of the invention, the term ink refers to any deformable mass (fluid, liquid) capable of being discharged from an ink-jet printing head such as suspensions, solutions, dispersions, pastes, lacquers, emulsions, sols and the like.

In the context of the invention, the term electrode is meant to include a plurality of electrodes which are (collectively) provided in accordance with a desired pattern. A plurality of electrodes may together form an electrode layer. An electrode layer may comprise a plurality of spatially separated mutually independently addressable electrodes. An electrode may be a common electrode for supplying charges to electroluminescent layers of different independently addressable EL elements (also referred to as EL pixels) of an EL device.

As usual, the term “comprising” in the expression “electrode comprising a metal or metal alloy” does not exclude the presence of further metals and/or metal alloys. In particular, the electrode may consist of a metal, a metal alloy or any mixture of metals and/or metal alloys. The electrode comprising a metal or a metal alloy is also referred to as the metal or metal alloy electrode.

In a related aspect, the invention relates to an electroluminescent device comprising a patterned electrode for supplying charges to an electroluminescent layer, the electrode comprising a metal or metal alloy and having a transverse profile with a maximum thickness of at least 5 μm. Preferably, the thickness is at least 10 μm or, better, at least 20 μm. At a maximum thickness of less than 5 μm, the contact angle becomes very small and the ink cannot spread easily to the desired width when the width to be obtained about 50 to 300 μm. Such electrode widths are typical for pixelated displays. At small contact angles typically less than 0.1 radian, the natural shape and size of the ink drop, if attained at all, is easily disturbed, rendering the ink-jet printing process unreliable. The thickness is defined as the dimension in the direction normal to the surface onto which the electrode is provided. Most convenient for ink-jetting are electrodes having a maximum thickness of 40 μm or more. Alternatively, ink-jet printing is conveniently performed when the maximum thickness is at least 40% of the width of the electrode.

An attractive feature of an electroluminescent device in accordance with this aspect of the invention is that the patterned electrode layer is obtainable by ink-jet printing of molten metal or metal alloy. If obtained by inkjet printing molten metal, the electrode has a shape a fluid resting on a surface would adopt if provided in accordance with the same pattern. The advantages of providing the electrode by ink-jet printing have been described hereinabove.

Ink-jet printing allows printing of features of as small as 20 μm, thus the patterned electrodes can be suitably used in multi-pixel EL devices having pixel sizes of 100 to 300 μm. Even high-definition displays having pixel sizes as small as 50 μm or smaller are accessible.

Furthermore, having a maximum thickness of at least 5 μm reduces the risk of pin-hole formation in the electrode. Pinholes, as is known in the art, lead to undesirable dark spot formation in the EL device. The thick electrode also provides a protective function for easily-damaged layers covered by it such as an organic electroluminescent layer.

When an individual ink drop is deposited on a substrate, the drop generally adopts an axially symmetric convex shape having a maximum thickness. Depending on the wettability of a drop with respect to the supporting surface, which is characterized by the contact angle between a drop and its supporting surface, the shape of the drop is more or less rounded. Typically, ink-jet heads deliver drops having a diameter in the range of 20 μm to 80 μm. When the ink drop is converted into a drop of electrode material the convex shape is generally conserved. If, upon conversion, in addition, the volume of the drop does not substantially change, a maximum thickness of at least 5 μm is conveniently and routinely obtainable.

In the case of a jet containing individual drops, by moving the ink-jet head relative to the surface onto which ink is to be deposited an array of drops is formed in accordance with a pattern. The drop frequency and speed at which the ink-jet head is moved relative to surface can be mutually attuned such that the array of drops merges to form a single continuous structure.

The purpose of the electrode layer is, in response to an applied voltage, to supply charges to an electroluminescent material typically provided in the form of a layer. A charge may be positive in that case also referred to as holes or negative in that case also referred to as electrons. Supplying charges involves transporting charges from locations outside the light-emitting area, for example from a contact pad, to locations, for example a particular pixel, inside the light-emitting area. This charge transport is referred to as lateral charge transport as the direction of transport is lateral to the surface on which the electrode is provided.

In addition, charge transport takes place wherein charges are transported away from the electrode and towards an electroluminescent layer. This is referred to as transverse charge transport as in a stacked EL device this transport is normal to the surface supporting the electrode. In case of a multi-pixel EL device, transverse charge transport typically takes place inside an EL pixel.

While being transversely transported, charges may be injected into a functional layer neighboring the electrode. The neighboring functional layer may be an electroluminescent layer or a charge transporting and/or injecting layer for transporting and/or injecting charges to a second neighboring functional layer located on the side of the charge transporting/injecting layer facing away from the electrode layer. Thus, the electroluminescent layer may be separated from the electrode by one or more functional layers such as charge transporting/injecting layers.

The advantages of ink-jet printing are best exploited if the electrode is provided in accordance with a pattern. Patterned electrodes can be used to provide an EL device capable of displaying an image, logo or other kind of sign.

Also, the EL device having patterned electrodes in accordance with the invention may serve as electrodes of independently addressable EL elements (also referred to as pixels), such as in segmented displays and matrix displays of the passive and active type.

Although in principle an inkjet printed layer of organic, or more specifically polymeric, electrically conductive material may also serve as electrode, the electroconductivity of such electrodes is found to be too low to provide sufficient lateral charge transport for practical display applications. For example in a passive matrix display, the voltage drop along such an organic electrode would lead to an unacceptable non-uniformity in brightness among pixels addressed by such an electrode.

As metals and metal alloys are sufficiently conductive for the purpose of supplying charges to the EL material, the choice of metal or metal alloy for this purpose is not critical and any metal or metal alloy may be used to manufacture the electrode.

The EL device comprises an electroluminescent material, generally in the form a layer, to which the electrode supplies charges. In the context of the invention, the type of EL material used is not critical and any EL material known in the art can be used. In particular, suitable are organic (polymeric) EL materials. Such material may include organic photo- or electroluminescent, fluorescent and phosphorescent compounds of low or high molecular weight. Suitable low molecular weight compounds are well known in the art and include tris-8-aluminium quinolinol complex and coumarins. Such compounds can be applied using vacuum-deposition method. Alternatively, the low molecular weight compounds can be embedded in a polymer matrix or chemically bonded to polymers, for example by inclusion in the main chain or as side-chains, an example being polyvinylcarbazole.

Preferred high molecular weight materials contain EL polymers having a conjugated repeating unit, in particular EL polymers in which neighboring repeating units are bonded in a conjugated manner, such as polythiophenes, polyphenylenes, polythiophenevinylenes, or, more preferably, poly-p-phenylenevinylenes. Particularly preferred are (blue-emitting) poly(alkyl)fluorenes and poly-p-phenylenevinylenes which emit red, yellow or green light and are 2-, or 2,5- substituted poly-p-phenylenevinylenes, in particular those having solubility-improving side groups at the 2- and/or 2,5 position such as C₁-C₂₀, preferably C₄-C₁₀, alkyl or alkoxy groups. Preferred side groups are methyl, methoxy, 3,7-dimethyloctyloxy, and 2-methylpropoxy. More particularly preferred are polymers including a 2-aryl-1,4-phenylenevinylene repeating unit, the aryl group being optionally substituted with alkyl and/or alkoxy groups of the type above, in particular methyl, methoxy, 3,7-dimethyloctyloxy, or, better still, 2-methylpropoxy. The organic material may contain one or more of such compounds. Such EL polymers are suitably applied by wet deposition techniques.

In the context of the invention, the term organic includes polymeric whereas the term polymer and affixes derived therefrom, includes homopolymer, copolymer, terpolymer and higher homologues as well as oligomer.

Optionally, the organic EL material contains further substances, organic or inorganic in nature, which may be homogeneously distributed on a molecular scale or present in the form of a particle distribution. In particular, compounds improving the charge-injecting and/or charge-transport capability of electrons and/or holes, compounds to improve and/or modify the intensity or color of the light emitted, stabilizers, and the like may be present.

The organic EL layer preferably has an average thickness of 50 nm to 200 nm, in particular, 60 nm to 150 nm or, preferably, 70 nm to 100 nm.

The ink-jet printed or patterned electrode may supply charges to the EL material via one or more charge transporting/injecting layers. Such functional layers may be hole-injecting and/or transporting (HTL) layers if the electrode supplies positive charges and electron-injecting and transport (ETL) layers if the electrode supplies electrons. Examples of EL devices comprising more than one functional layer are a laminate of anode/HTL layer/EL layer/cathode, anode/EL layer/ETL layer/cathode, or anode/HTL layer/EL layer/ETL layer/cathode.

If the metal or metal alloy electrode provides lateral charge transport from outside the light-emission area to a particular pixel, the charge injecting/transporting layer only has to provide charge transport within a pixel, in which case the conductivity of the charge injecting/transporting layer can be much smaller than the conductivity of the electrode.

If the EL device is of the diode type, the work function of a charge injecting/transporting layer is preferably selected intermediate of the functional layers neighboring said layer in order to improve charge injection into the EL material.

Suitable materials for the hole-injecting and/or hole-transport layers may be metal or metal alloys or organic materials such as aromatic tertiary amines, in particular diamines or higher homologues, polyvinylcarbazole, quinacridone, porphyrins, phthalocyanines, poly-aniline and poly-3,4-ethylenedioxythiophene.

Suitable materials for electron-injecting and/or electron-transport layers (ETL) include metals, metal alloys, oxadiazole-based compounds and aluminiumquinoline compounds.

If ITO is used as the anode, the EL device preferably comprises a 50 to 300 nm thick layer of the hole-injecting/transporting layer material poly-3,4-ethylenedioxythiophene or a 50 to 200 nm thick layer of polyaniline.

Generally, the EL device comprises a substrate. If the EL device is arranged to emit light via the substrate, the substrate is to be transparent with respect to the light to be emitted. Suitable substrate materials include transparent synthetic resin which may or may not be flexible, quartz, ceramics and glass. The substrate provides the supporting surface for the relief pattern.

In one embodiment, the EL device is an organic or more specifically a polymeric EL device comprising an organic (polymeric) electroluminescent layer disposed between a first and a second electrode. Generally, the organic EL device is a stacked EL device in which the EL layer is sandwiched between the first and the second electrode. Charge injecting/transporting layers, examples of which are described hereinabove, may be provided between an electrode and an electroluminescent layer.

In a preferred embodiment the electrode layer comprises a metal or metal alloy having a low melting point.

If the metal or metal alloy from which the electrode is made has a low melting point the electrode can be ink-jet printed from the melt which is more convenient and energy efficient the lower the melting point. Also, the ink-jet printing head may be of a simpler structure and have a longer service life the lower the melting point.

If the molten metal or metal alloy is to be provided on a surface covered with functional layers of the EL device, such as the EL layer, the melting point is selected such that said (temperature-sensitive) functional layers are not thermally degraded by the molten metal or metal alloy.

Whether or not thermal degradation has occurred may be evaluated by examining the performance of the EL device by measuring, for example, the current voltage, current voltage luminescence characteristics or service life of the device. This performance may be compared with the performance of a corresponding EL device having a vacuum-deposited electrode layer of the same electrode layer material in terms of elemental composition.

In view of the above, a preferred embodiment is an electroluminescent device in accordance with the invention wherein the metal or metal alloy has a melting point of 250° C. or less.

Preferably, the metal or metal alloy has a melting point less than 250° C., or better 200° C., or still better 175° C. Preferably, the melting point is less than 150° C. It is observed that a liquid metal electrode is surprisingly resistant to mechanical shock and not is easily removed from the substrate. Generally, however, it is preferred that the electrode is solid under a variety of conditions of use of the EL device. Therefore the melting point of the metal or metal alloy is preferably exceeds room temperature, or is at least 30° C., or better 45° C. At least 60° C. for displays in telecommunication equipment. For automotive applications, at least 80° C. is preferred.

Commercially available, low cost, low-melting metals and metal alloys are those which comprise elements selected from the group consisting of In, Sn, Bi, Pb, Hg, Ga and Cd. Apart from a broad spectrum of melting points, said metals also offer a broad spectrum of other properties which are important, such as sensitivity to oxidation, adhesion to other materials, coefficient of thermal expansion, ductility, dimensional stability, degree of shrinkage upon solidification and wetting. In applications in which toxicity is an important factor, alloys containing Hg or Cd, such as Sn:(50 wt. %):Pb (32 wt. %):Cd (18 wt. %) alloy are not to be preferred. If a somewhat flexible EL device is necessary, it is advantageous to use a ductile low-melting metal, such as indium (melting point 157° C.) or Sn(35.7 wt. %):Bi(35.7 wt. %):Pb(28.6 wt. %), which has a melting point of 100° C. To minimize stresses caused by solidification, a metal which, upon solidification, does not form crystalline domains and exhibits little shrinkage, such as Bi(58 wt. %):Sn(42 wt.%), melting point 138° C., is preferred.

EL devices of the diode type, also referred to as light-emitting diodes, typically comprise an electroluminescent layer disposed between a hole-injecting electrode, also referred to as the anode, and an electron-injecting electrode, also referred to as the cathode.

The anode may be an ink-jetted electrode in accordance with the invention and, in order to achieve efficient hole injection, is typically made of a high work function material. A suitable high work function electrode material has a work function of more than 4.5 eV. Examples include metals such as Au, Ag, Pt, Pd, Cu and Mo.

Alternatively, the anode may comprises oxidic conductors such as indium oxides, tin oxides, zinc oxides, antimony oxides. Preferably, the anode is made of a transparent conductor such as an indiumtinoxide (ITO). As the person skilled in the art will know, there are many transparent oxidic conductors which can be provided from solution. Generally, such methods comprise a heating step at 300° C. or more to obtain layers of sufficient conductivity. Therefore, such methods are particularly suitable if applied substrates provided with temperature-resistant EL or other functional layers. In the case of temperature sensitive materials, PPVs are generally such materials, the ink-jetted anode is deposited prior to deposition of the temperature-sensitive functional materials. As an example of such a method, SnO₂ and SbO₂ (6 to 15% SnO₂, rest SbO₂) particles, 10-20 nm in diameter, are added to ethanol to obtain a 5 wt. % suspension. Ink-jet printing a layer on glass and heating 50 min in air at 300° C. or better 500° C. results in ink-jet printed anode of an antimonytinoxide.

A preferred embodiment is an electroluminescent device in accordance with the invention wherein the electrode is an electrode for supplying electrons to the electroluminescent layer.

Generally, a typical EL device of the diode type is provided on a transparent substrate, the anode facing the substrate. Because in this configuration functional layers are already present when the cathode layer is to be provided, the deposition of the cathode is to be compatible with the functional layers, that is the deposition should not damage the functional layers previously deposited. An ink-jet printed cathode is suitable for this purpose.

A preferred embodiment is an electroluminescent device in accordance with the invention wherein the electrode has a work function of 4.5 eV or less.

In order to achieve efficient electron injection, the metal or metal alloy is to have a low work function. Preferably, the work function is less than 4.0 eV, or better 3.5 eV. Electron injection is improved further if the work function is less than 3.0 eV or better less than 2.5 eV. Examples of low work function metals include alkali metals, earth alkali metals, Al, Sc, Sr, Ca, Ga, In, Na, Li, Cs, Yb, Ba and Mg and alloys comprising these metals such as Ba:Al, Mg:Ag and Li:Al. Low work function metals are highly reactive in particular towards water and/or oxygen. An improved cathode in this respect is a dual metal layer cathode of a first low work function metal layer and a second metal layer having a higher work function than the first metal layer, the first low work function metal layer facing the EL layer. An example of such a dual cathode layer is a Ba:Al cathode layer.

Particularly preferred are EL devices having an electron-injecting layer comprising metal or metal alloy having a low melting point and a low work function, such as In and Ga and low-melting alloys comprising these metals.

A preferred embodiment is an electroluminescent device in accordance with the invention, further comprising a relief pattern for patterning the pattern-wise ink-jet printed electrode.

In case a size naturally adopted by a drop of ink when deposited on a surface is larger than a desired size, in particular in a direction parallel to the surface onto which it is deposited, and as a consequence, resulting in an electrode layer not in accordance with the desired pattern, a relief pattern can be used to obtain the desired size. When ink is deposited in the spaces defined by the relief pattern, the ink cannot spread beyond the confines of the spaces defined by the relief pattern.

In a preferred embodiment, the EL device has a relief pattern which is also used to pattern other functional layers of the EL device such as an EL layer, a charge transport layer and/or a charge injecting layer. In that case a relief pattern has to be provided anyway and the relief pattern for patterning the electrode can be integrated with and provided at the same time as the relief pattern for the other functional layers.

The type of relief pattern and method of providing the relief pattern are not critical. If the relief pattern is to remain a permanent part of the EL device the relief pattern must be electrically insulating to avoid short circuits between electrodes. Most conveniently, the relief pattern is provided by means of conventional photolithography involving the patterning of a photoresist.

In a particular embodiment, the EL device in accordance with the invention is an electroluminescent device, wherein the device is a matrix display device of the passive type comprising one or more electroluminescent layers sandwiched between row electrodes and column electrodes, independently addressable electroluminescent elements being formed at crossings of row and column electrodes, wherein the row electrodes are pattern-wise inkjet printed electrodes comprising a metal or a metal alloy.

The size of the EL elements is selected in accordance with the application. For high definition, pixels of 10 to 75 μm can be used. For less demanding applications a pixel size of 100 to 300 μm may be sufficient. In full-color displays, red, green and blue light-emitting pixels are required which are grouped in triplets each triplet forming an RGB pixel. For example, the red, green and blue pixels may each measure 100 by 300 μm giving an RGB pixel of 300 by 300 μm. To maximize the fill-factor, defined as the total area available for light emission divided by the total area of the display, the distance at which the row and column electrodes are spaced are kept as small as possible. Typically, row electrodes are spaced at distances of 10 to 40 μm or better 15 to 30 μm. The same applies to the column electrodes.

As the EL device in accordance with the invention requires a potential of only a few volts to provide a brightness suitable for display purposes and/or consumes a small amount of power the EL device is particularly suitable for displays of battery operated and/or portable, in particular hand-held, electronic equipment such as lap top computers, palm top computers, personal organizers, mobile phones optionally provided with internet access or other services requiring the presentation of (video) images. The EL device allows internet data and image data to be displayed at video rates.

In another aspect, the invention therefore relates to a battery-operated and/or hand-held electronic device, such as a mobile phone, provided with an EL display device in accordance with the invention.

In another aspect, the invention relates to a method of manufacturing an electroluminescent device.

More specifically, it relates to a method of manufacturing an electroluminescent device comprising a metal or metal alloy electrode provided in accordance with a desired pattern, said method comprising the deposition of a metal or metal alloy electrode in accordance with the desired pattern on a substrate surface by means of one or more deposition steps, said deposition including a deposition step of ink-jet printing in accordance with the desired pattern or a pattern complementary thereto.

The advantages of providing an electrode layer by means of ink-jet printing have been mentioned hereinabove.

A suitable embodiment of the method comprises:

providing a first electrode layer;

providing an electroluminescent layer;

providing a second electrode layer;

wherein at least the second electrode layer is a pattern-wise ink-jetted electrode layer. In one variant the first electrode layer is a cathode layer and the second an anode layer. In another the first electrode layer is an anode layer and the second is cathode layer. Most conveniently, the functional layers are provided on a substrate which is preferably transparent to the light to be emitted by the EL device. As mentioned hereinabove one or more other functional layers such as charge transport and injecting layers may be disposed between any (ink-jetted) electrode layer and an electroluminescent layer.

A particularly suitable method for depositing an electrode layer of low-melting metal or metal alloy is a method of manufacturing an electroluminescent device comprising a metal or metal alloy electrode provided in accordance with a desired pattern, said method comprising a deposition step of ink-jet printing molten metal or metal alloy on a surface in accordance with the desired pattern thus forming, upon cooling of the molten metal or metal alloy ink-jet printed onto the surface, the metal or metal alloy electrode.

The method involves discharging molten metal or metal alloy from a heated ink-jet head. When deposited on a surface of lower temperature the molten metal cools down and, dependent on the melting point of the metal (alloy) employed, solidifies. In order to reduce the temperature shock the substrate surface may be heated. Substrate heating may also be employed to increase the wettability of the substrate. After the electrode layer is formed it may be subjected to a post-treatment involving heating the electrode layer above its melting point and then let it become solid again in order to remove any stresses possibly built into the layer during ink-jet printing.

Ink-jet printing of molten metal or metal alloy is particularly attractive for depositing low work function metals or metal alloys having a low melting point. Only a single deposition step is required to form the electrode. In order to prevent oxidation of the readily oxidizable low work function metal, ink-jet printing is to be carried out in an inert atmosphere such as a nitrogen or argon atmosphere.

A dual metal electrode layer can also be provided in this manner by means of discharging molten metal composition containing the metal or metal alloys of both layers, which molten metal, when deposited on the surface, phase separates to form the dual layer electrode upon cooling.

Another embodiment of the method in accordance with the invention is a method of manufacturing an electroluminescent device comprising a metal or metal alloy electrode in accordance with a desired pattern, the deposition of the electrode comprising a deposition step of ink-jet printing a precursor ink capable of being converted to a metal or a metal alloy onto a surface in accordance with the desired pattern and then converting the precursor ink ink-jet printed onto the surface to the metal or the metal alloy thus forming the electrode in accordance with the desired pattern.

This method is in some aspects a generalization of the molten metal method described above. However, generally the precursor ink will be a fluid in which the metal or metal alloy is present in some convenient form such as a (metal) sol, a dispersion, a solution or an emulsion. This method is of particular use if an electrode layer comprising metal or metal alloy having a high melting point is to be provided.

Depending on the type of precursor ink used, the conversion may be effected by applying, for example, heat, radiation or exposure to reduced pressure and may involve just removal of a solvent or (in addition) chemical conversion.

A further embodiment is a method of manufacturing an electroluminescent device comprising a metal or metal alloy electrode in accordance with a desired pattern, said method comprising:

ink-jet printing a selection layer onto a surface in accordance with the desired pattern or a pattern complementary thereto, the selection layer enabling metal, metal alloy or precursor ink from which metal or metal alloy is obtainable to be deposited selectively on the surface;

providing, optionally by means of the precursor ink, metal or metal alloy selectively in accordance with the desired pattern thus forming the metal or metal alloy electrode.

In one embodiment of the method, the selection layer has a higher affinity for the metal, metal alloy or precursor ink than the parts of the surface which are not covered by the selection layer. In that case the pattern of the selection layer corresponds to the desired pattern. An example of such a selection layer is an activation layer onto which metal or metal alloy can be selectively deposited by means of electroless plating. Such activation layers and inks used for preparing such activation layers are well known in the art. As a further example, the selection layer is an adhesion layer capable of selectively adsorbing molten metal or metal alloy or a precursor ink convertible to such a metal or metal alloy. Such adhesion layers are well known in the art.

In another embodiment of the method, the selection layer has a lower affinity for the metal, metal alloy or precursor ink than the parts of the surface which are not covered by the selection layer. In that case the pattern of the selection layer is complementary to the desired pattern. This type of selection layer has the advantage that the selection layer is not part of the path along which the electrode supplies charges to the EL layer. An example of such a selection layer is a layer which is poorly-wetting with respect to molten or metal alloy or a precursor composition convertible to such a metal or metal alloy. Such layers are well known in the art. In general, organic, apolar layers such as photoresist layers are suitable for this purpose.

In all embodiments involving the selection layer, a simple non-selective coating method such as dip coating, curtain coating, doctor blading, spin-coating or spray coating can be used to deposit the electrode material.

Although the invention is discussed hereinabove mainly in relation to an electroluminescent device of the diode type, also referred to in the art as a light emitting diode, the device in accordance with the invention can be any electroluminescent device. It may be of the inorganic type but preferably is of the organic type. It may be a unipolar electroluminescent device, that is a device in which injection of charge carriers of only one polarity is sufficient to generate light. It may also be of the bipolar type which requires injection of both holes and electrons to generate light. The latter type includes the light emitting cell (LEC) as disclosed in U.S. Pat. No. 5,682,043 which does not require electrodes of different work function to get observable light emission and the light emitting diode (LED) which requires electrodes of high work function to inject holes and an electrode of low work function to inject electrons. Also included are electroluminescent devices where the charge injecting electrodes are arranged subjacent or, alternatively, adjacent with respect to each other.

These and other aspects of the invention will be apparent from and elucidated with reference to the embodiments described hereinafter.

In the drawings:

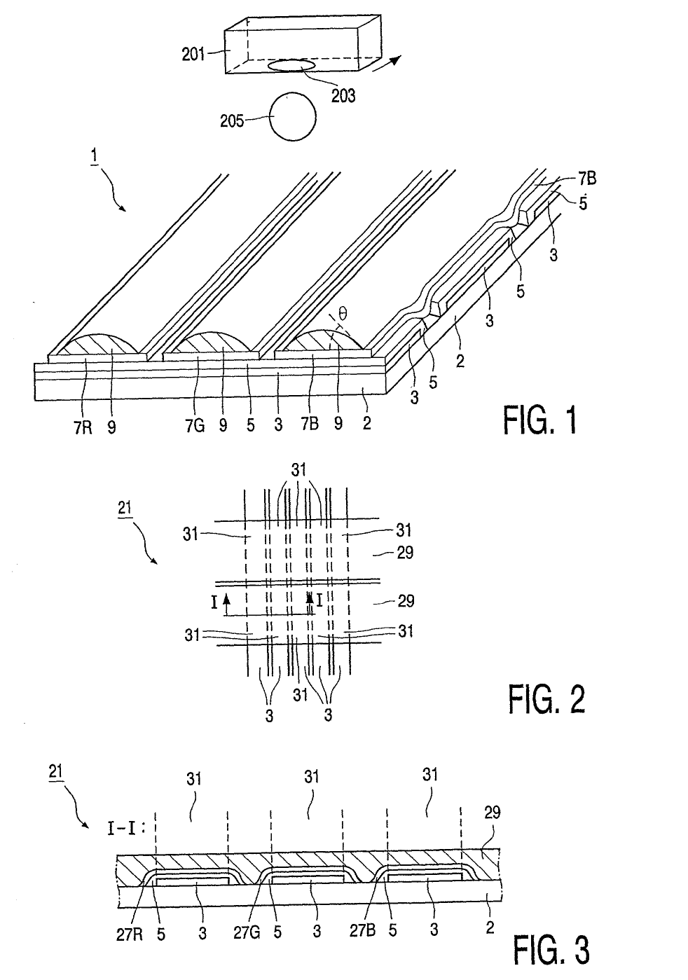

FIG. 1 shows, schematically, in a perspective plan view, a cross-section of an embodiment of an EL device of the light emitting diode type comprising ink-jet printed electrodes in accordance with the invention,

FIG. 2 shows, schematically, a plan view of a further embodiment of an EL device comprising an ink-jet printed electrode layer in accordance with the invention,

FIG. 3 shows, schematically, a cross-sectional view along the line I-I in FIG. 2,

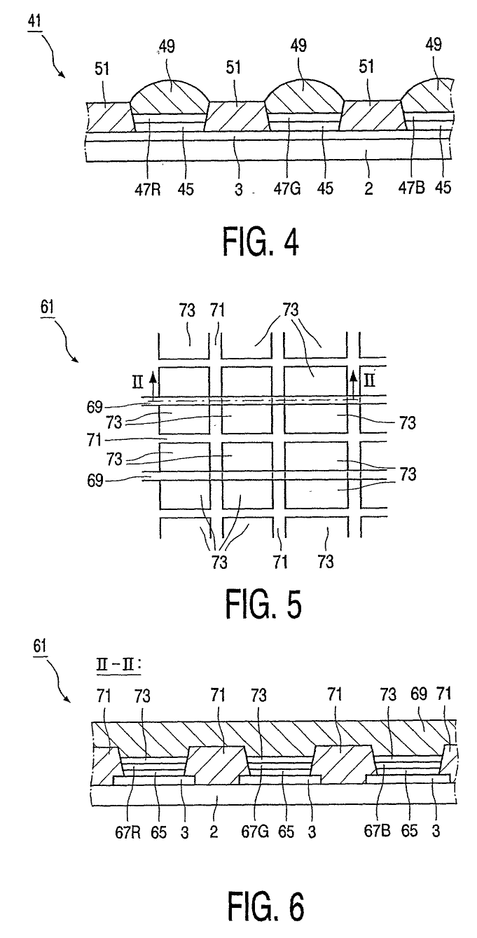

FIG. 4 shows, schematically, a cross-sectional view of an embodiment of a passive matrix EL device in accordance with the invention,

FIG. 5 shows, schematically, a plan view of another embodiment of an EL device comprising an ink-jet printed electrode layer in accordance with the invention,

FIG. 6 shows, schematically, a cross-sectional view along the line II-II in FIG. 5,

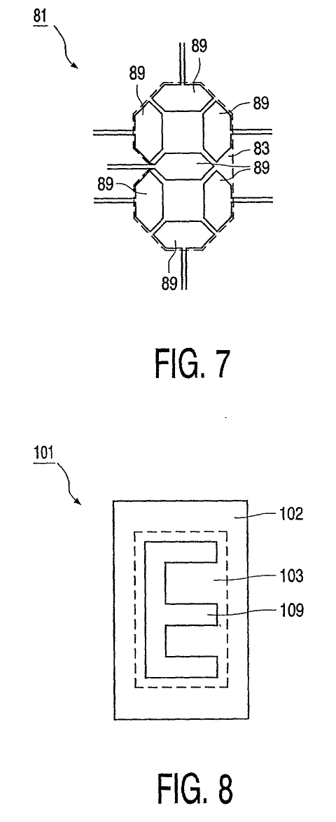

FIG. 7 shows, schematically, a plan view of an embodiment of a segmented EL display device in accordance with the invention, and

FIG. 8 shows, schematically, a plan view of a further EL device in accordance with the invention.

FIG. 1 shows, schematically, in a perspective plan view, a cross-section of an embodiment of an EL device of the light emitting diode type comprising ink-jet printed electrodes in accordance with the invention.

The shown EL device 1 has a substrate 2, generally transparent to the light to be emitted by the EL device 1 but this is not essential for the invention. The substrate 2 is provided with column electrodes 3 provided in accordance with a pattern of lines and spaces. The column electrodes 3 supply charges, via a charge transporting/injecting layer 5, to the electroluminescent layers 7R, 7G, 7B, which together form a patterned EL layer. In a full-color device, the electroluminescent material of the EL layers 7R, 7G and 7B are grouped in triplets of neighboring EL layers, each EL layer of a triplet 7R, 7G, 7B emitting red, green and blue light respectively when the EL device 1 is in operation. However, this is not essential for the invention. Each EL layer 7R, 7G and 7B may, for example, emit the same color or the device may be a multi-color device having for example two types of emitting layers. The EL layers 7R, 7G, 7B run transversely to the column electrodes 3. Substantially covering the EL layers 7R, 7G, 7B, a plurality of ink-jet printed row electrodes 9 is provided in accordance with a lines and spaces pattern running transversely to the electrodes 3. At crossings of the column electrodes 3 and row electrodes 9, more specifically at areas of overlap of the column electrodes 3, the charge transport layer 5, the EL layers 7R, 7G, 7B and the row electrodes 9, independently addressable EL elements are formed which together form a passive matrix display device. The row electrodes 9 are ink-jet printed using the ink-jet head 201 having a nozzle 203 from which ink drops 205 are discharged. The transverse profile of the row electrodes 9 in the plane normal to the longitudinal direction of the row electrodes 9 has the characteristic shape of that of a drop of fluid resting on a surface and is characterized by a contact angle θ with respect to the supporting substrate surface. The row electrodes 9 have a transverse profile with a maximum thickness of 5 to 100 μm. The row electrodes 9 having this specific transverse profile are obtainable by ink-jetting ink drops 205 of molten metal or metal alloy on the substrate surface.

Suitably, but this is not essential for the invention, the column electrodes 3 are transparent to the light to be emitted. A convenient choice of transparent column electrode material is ITO in which case the column electrodes 3 generally serve to supply holes to the EL layers 7R, 7G, 7B. In that case the ink-jet printed row electrodes 9 serve to supply electrons to said EL layers.

FIG. 2 shows, schematically, a plan view of a further embodiment of an EL device comprising an inkjet printed electrode layer in accordance with the invention.

FIG. 3 shows, schematically, a cross-sectional view along the line I-I in FIG. 2.

Referring to FIGS. 2 and 3, the EL device 21 is a passive matrix EL device comprising independently addressable EL elements 31 formed at crossings of column electrodes 3 and row electrodes 29. Between the electrodes 3 and 29 and running parallel to the column electrodes 3, EL layers 27R, 27G, 27B are sandwiched. The column electrodes 3 supply charges to the EL layers 27R, 27G, 27B via the charge transporting/injecting layer 5. The row electrodes 29 are ink-jet printed electrodes having the “droplet resting on a surface” transverse profile as shown in FIG. 1.

FIG. 4 shows, schematically, a cross-sectional view of an embodiment of a passive matrix EL device in accordance with the invention.

The EL device 41 is similar to EL device 1, except that EL device 41 has a relief pattern 51 for patterning the ink-jet printed row electrodes 49. The relief pattern also serves to pattern the EL layers 47R, 47G, 47B. In this embodiment, in order to reduce cross-talk and in particular leakage current between neighboring column electrodes 3, the relief pattern is also used for patterning the charge transporting/injecting layer 45, but this is not essential for the invention. Suitably, the EL layers 47R, 47G, 47B and charge transporting/injecting layer 45 may be provided using ink-jet printing. Using the same relief pattern 51 for patterning all these layers allows the EL device 41 to be manufactured in a simple and effective manner.

FIG. 5 shows, schematically, a plan view of another embodiment of an EL device comprising an ink-jet printed electrode layer in accordance with the invention.

FIG. 6 shows, schematically, a cross-sectional view along the line I-II in FIG. 5.

The EL device 61 is similar to EL device 21 and comprises a substrate 2 onto which column electrodes 3 are provided. EL layers 67R, 67G, 67B are sandwiched between said column electrodes 3 and ink-jet printed row electrodes 69 comprising metal or metal alloy. However, in contrast to EL device 21, the EL device 61 has a relief pattern 71 for patterning the EL layers 67R, 67G, 67B. In this embodiment, in order to reduce cross-talk and in particular leakage current between column electrodes 3, the relief pattern is also used for patterning the charge transport/injecting layer 65, but this is not essential for the invention. The ink-jet printed row electrodes 69 supply charges to the EL layers 67R, 67G, 67B via the patterned charge transporting/injecting layer 73. The electrodes provide the lateral charge transport, that is the transport from outside the display area to appropriate parts of the display area, whereas vertical charge transport is provided via the patterned charge transporting/injecting layer 73. Because the layer 73 only needs to provide lateral charge transport across an area typically the size of a pixel, this arrangement allows the use of a charge transporting/injecting material which has excellent injecting properties but whose conductivity is insufficient to provide lateral charge transport across the entire light-emitting display area on the one hand and metal electrodes having sufficient conductivity yet unsatisfactory charge injecting properties on the other hand. In order to reduce cross-talk and in particular leakage current between row electrodes 69, a relief pattern may, but this is not essential for the invention, be used for patterning the charge transport/injecting layer 73 into mutually separate charge transporting/injecting areas such that neighboring row electrodes 69 are not connected via any such area. In that case the relief pattern 71 is provided in the form of a matrix, as shown in FIG. 5, of which the rows serve to pattern the layer 73 accordingly and the of which columns serve to pattern the EL layers 67R, 67G, 67B. The EL device has independently addressable electrodes at crossings of the column electrodes 3 and row electrodes 69. The light-emitting area of an EL element of this EL device 61 corresponds to the area of overlap of an EL layer 67R, 67G, 67B, the charge transporting/injecting layer 65 and the charge transporting/injecting layer 73.

FIG. 7 shows, schematically, a plan view of an embodiment of a segmented EL display device in accordance with the invention.

The EL device 81 has a common electrode 83, indicated by the area circumscribed by the dashed line, and a segmented electrode layer of ink-jet printed electrode segments 89 comprising metal or metal alloy for supplying charges to an EL layer (not shown) of the EL device 81. The electrode segments 89 are provided in accordance with a pattern representing the number 8 and are independently addressable enabling the numbers 0 through 9 to be displayed by supplying a voltage between the common electrode 83 and the appropriate segment electrodes 89.

FIG. 8 shows, schematically, a plan view of a further EL device in accordance with the invention.

The EL device 101 comprises a substrate 102 onto which an electrode 103 is provided for supplying charges to an EL layer (not shown) of the EL device. The device further comprises an inkjet printed electrode 109 comprising metal or metal alloy provided in accordance with a pattern in the form of the letter ‘E’. When a suitable voltage is applied to the electrodes 102 and 103 the letter ‘E’ lights up.

### EXAMPLE 1

An ink-jet printer equipped with an ink-jet head having a controlled heater and a single nozzle having a nozzle diameter of 67 μm (microdispenser head, type MD-K-140H), ink reservoir (type MD-V-304), vertical container and tubing (type MD-H-715H) and driver electronics (type MD-E-201H) all supplied by Microdrop is, in its entirety, brought to a temperature of 42° C. and the ink reservoir filled with liquid gallium. Gallium is a low-melting metal, melting point about 30° C., and has a low work function of about 4.2 eV. The nozzle delivers drops of gallium which are 90 μm in diameter. Because the viscosity of molten gallium is low, only a few cP, the nozzle is provided with a damping throttle of 40 μm. Below the nozzle a nitrogen gas flow is established in order to prevent the discharged molten metal drops from being oxidized.

A soda-lime glass substrate is placed on a moveable XY-table and the ink-jet head is positioned over the substrate. Both table and substrate are at room temperature (about 23° C.).

While moving the XY-table at a speed 20 min/s and discharging ink drops of molten gallium at a drop frequency of 75 Hz, a continuous line of metal is printed onto the surface of the substrate thus forming a patterned ink-jet printed electrode of a low work function metal. After the molten metal has solidified a 110 μm wide line of Ga metal is obtained suitable for use as an electrode in an EL device. The electrode has a transverse profile with a maximum of about 70 μm. The profile obtained by connecting the points of maximum thickness of the electrode along the path followed by the ink-jet head, shows an undulation having minima at 70 μm and maxima at 90 μm thickness, the maxima corresponding to positions where ink drops have hit the substrate during ink-jetting. The transverse profile in the plane normal to the direction of the line is convex in shape. More particular, it has the shape of a cross-section of a drop of liquid resting on surface.

If the experiment is repeated using a drop frequency of 300 Hz, a continuous line of Ga metal is obtained which is about 185 μm wide and has transverse profile with a maximum thickness of about 45 μm. The profile obtained by connecting the points of maximum thickness of the electrode along the path followed by the ink-jet head, shows an undulation having minima at 45 μm and maxima at 66 μm thickness, the maxima corresponding to positions where ink drops have hit the substrate during ink-jetting. Any line width between 110 μm and 185 μm is obtainable by selecting a suitable drop frequency between 75 and 300 Hz.

1. An electroluminescent device comprising a pattern-wise ink-jet printed electrode for supplying charges to an electroluminescent layer of the electroluminescent device, the electrode comprising a metal or a metal alloy.

2. An electroluminescent device comprising a patterned electrode for supplying charges to an electroluminescent layer, the electrode comprising a metal or a metal alloy and having a transverse profile with a maximum thickness of at least 5 μm.

3. An electroluminescent device as claimed in claim 1 or 2 wherein the metal or metal alloy has a melting point of 250° C. or less.

4. An electroluminescent device as claimed in claim 1, 2 or 3 wherein the electrode is an electrode for supplying electrons to the electroluminescent layer.

5. An electroluminescent device as claimed in claim 4 wherein the electrode has a work function of 4.5 eV or less.

6. An electroluminescent device as claimed in claim 1, 2, 3 or 4 further comprising a relief pattern for patterning the pattern-wise ink-jet printed electrode.

7. An electroluminescent device as claimed in any one of the claims 1 to 6, wherein the device is a matrix display device of the passive type comprising one or more electroluminescent layers sandwiched between row electrodes and column electrodes, independently addressable electroluminescent elements being formed at crossings of row and column electrodes, wherein the row electrodes are pattern-wise ink-jet printed electrodes comprising a metal or a metal alloy.

8. A battery-operated and/or hand-held electronic device, such as a mobile phone, provided with an electroluminescent device as claimed in any of the claims 1 to 7.

9. A method of manufacturing an electroluminescent device comprising a metal or metal alloy electrode provided in accordance with a desired pattern, said method comprising the deposition of a metal or metal alloy electrode in accordance with the desired pattern on a substrate surface by means of one or more deposition steps, said deposition including a deposition step of inkjet printing in accordance with the desired pattern or a pattern complementary thereto.

10. A method of manufacturing an electroluminescent device comprising a metal or metal alloy electrode provided in accordance with a desired pattern as claimed in claim 9, said method comprising a deposition step of ink-jet printing molten metal or metal alloy on a surface in accordance with the desired pattern thus forming, upon cooling of the molten metal or metal alloy ink-jet printed onto the surface, the metal or metal alloy electrode.
